(19) United States
(12) Patent Application Publication
(10) Pub. No.: US 2025/0285834 A1
(43) Pub. Date: Sep. 11, 2025

(54) ELECTRON MICROSCOPE IMAGING STAGES AND SYSTEMS

(71) Applicant: UNIVERSITY OF KANSAS, Lawrence, KS (US)

(72) Inventor: Eduardo ROSA-MOLINAR, Lawrence, KS (US)

(21) Appl. No.: 18/858,550

(22) PCT Filed: Apr. 21, 2023
(86) PCT No.: PCT/US2023/019475

§ 371 Date: Oct. 21, 2024

(51) Int. Cl. H01J 37/22; H01J 37/20

(52) U.S. Cl. CPC H01J 37/228; H01J 37/20

(57) ABSTRACT

The disclosure describes imaging systems adapted for use with a plurality of detectors and configured for use in a variety of electron microscopes. Also, methods of using such systems are disclosed.

### CROSS-REFERENCE TO RELATED APPLICATIONS

This application claims benefit of U.S. Application Ser. No. 63/333,538, filed on Apr. 21, 2022, which is hereby incorporated herein by reference in its entirety.

### BACKGROUND

Electron microscopy can be advantageously used to investigate the ultrastructure of biological samples such as cells and tissue, polymer resin samples, and crystalline samples such as inorganic substances. Two types of electron microscopes are known: scanning electron microscopes (SEMs) and transmission electron microscopes (TEMs).

In an electron microscope column, incident electrons are accelerated into, for example, epoxy resin-embedded samples (FIG. 1). A number of interactions between the accelerated electrons and atoms contained within the resin-embedded sample result in elastic and inelastic scattering of electrons (known as the electron interaction volume). A number of signals generated (i.e., secondary electrons, backscattered electrons, cathodoluminescence, Auger electrons, characteristic X-rays, and Bremsstrahlung X-rays) can be used for high-resolution electron microscopic imaging of ultrastructural features of cell and tissue organelles.

Recently, volume electron microscopy (VEM) gained a lot of interest as it allows analyzing large volumes. Initial procedures for VEM were developed to study the structure of the neural networks in a brain. Modern neuroscience models are often relying on data obtained from serial sectioning brain tissue and subsequent reconstruction. Realistic and meaningful analysis requires morphometric analysis at the ultrastructural level over large sample volumes. Large volumes are required to be statistically relevant and usable for model building.

However, there are still a lot of challenges associated with electron microscopy. Some of the challenges relate to artifacts produced during the imaging process when the samples are not adequately conductive. These challenges were overcome by researchers associated with this disclosure have developed a mechanically flexible and bendable conductive tape that holds tissue, permits nanoscale cellular imaging, and eliminates charging artifacts resulting from the electron beam in scanning electron microscopes, transmission electron microscopes, etc. The conductive tape can also be used for optical light microscopes to transmit light through the substrate for bright-field and fluorescence imaging.

An additional challenge of the volume tissue imaging relates to a lack of automated systems for tape-collecting ultramicrotomy that can be directly transferred into an electron microscope chamber and be imaged without any additional manipulations of the samples.

To take advantage of high-resolution microscopies, the life sciences need better sample preparation workflows, reagents that will overcome charging and sample damage caused by electron beam-sample interactions in the electron microscope, and tools for accurate microscopic imaging in both two dimensional and three-dimensional views. These needs and other needs at least partially satisfied by the present disclosure.

### SUMMARY OF THE DISCLOSURE

Provided herein are imaging systems for use in an electron microscope. The systems can be used, for example, to perform correlative light and electron microscopy on samples, including samples disposed on a sample containing tape.

In some aspects, the imaging system can comprise a stage that comprises a base plate dimensioned to be received and seated within an electron microscopy stage; a stage body extending vertically from the base plate, the stage body comprising a front face, a rear face, a top surface, a hollow chamber formed within the stage body and extending from the front face towards the rear face along an axis substantially parallel to the base plate; an imaging aperture formed within the top surface; and a beam path extending from the imaging aperture through the stage body to the chamber along an axis substantially perpendicular to the base plate. The imaging system can further comprise a coupler sized to be advanced and seated within the chamber, the coupler comprising a reflector disposed within a housing; and a fastener structured to operatively couple an optical element to the housing, wherein when the optical element is operatively coupled to the housing via the fastener and the coupler is seated within the chamber, the optical element, reflected and beam path are aligned so as to crease a path for light to travel from the optical element to the reflector through the beam path and the imaging aperture.

In some examples, the reflector can comprise, for example, a mirror or polished metal surface.

In some examples, the reflector can be retained within an adjustable bracket. One or more set screws can be coupled to the adjustable bracket such that rotation of the one or more set screws adjusts the orientation of the reflector. This can allow a user to adjust the optical alignment of the reflector relative to the optical element, beam path, and imaging aperture.

In some examples, the fastener can comprise a ferrule sized to accept a fiber optic cable. In other examples, the fastener can comprise a threaded fastener dimensioned to couple to a collimator; wherein the collimator is operatively connected to a fiber optic cable. In some of these embodiments, the fiber optic cable can comprise a multistrand fiber optic cable (e.g., a 2-channel fiber optic cable). The first strand of the multistrand fiber optic cable can be optically connected to a light source (e.g., one or more LEDs, or a laser) and a second strand of the multistrand fiber optic cable is optically connected to a detector (e.g., a digital camera or PMT)

In some examples, the chamber can be substantially cylindrical. In some examples, the coupler can also be substantially cylindrical and sized to be advanced and seated within the cylindrical chamber.

In some examples, the stage and the coupler are adapted for a high vacuum environment.

In some examples, the system can further comprise a t-base adaptor coupled to the base plate of the stage.

In some examples, the system can further comprise a reel-to-reel frame assembly operatively coupled to the stage. In some examples, the reel-to-reel frame assembly operatively coupled to the stage via a mounting bracket fastened to the rear face of the stage body. In certain embodiments, the rear face of the stage can comprise one or more threaded holes adapted to receive fasteners for attaching the reel-to-reel frame assembly to the stage.

In some examples, the reel-to-reel frame assembly can comprise a strut having a first surface and an opposite second surface, a first end and a second end, wherein the strut detachably holds: (i) a feeder motor and a take-up motor coupled to the second surface of the strut such that the feeder motor is spaced from the take-up motor by a predetermined distance; (ii) a first rod detachably coupled with the feeder motor through the strut, such that the first rod extends from the first surface of the strut, wherein the feeder motor is configured to spin the first rod at a predetermined speed, and (iii) a second rod detachably coupled with the take-up motor through the strut, such that the second rod extends from the first surface of the strut, wherein the take-up motor is configured to spin the second rod at a predetermined speed that is the same or different as the predetermined speed of rotations of the first rod; and a feeder reel having a top portion and a bottom portion detachably and rotatably coupled to the first rod and a take-up reel having a top portion and a bottom portion detachably and rotatably coupled to the second rod. The feeder reel can be configured to relay a sample-containing tape to the take-up reel at a first speed.

In some examples, the feeder reel and the take-up reel can each comprise two wheels connected with a spool. The spool can be adapted for receiving and relaying the sample-containing tape. In some of these examples, each of the two wheels and the spool can be formed from aluminum and/or aluminum alloy having predetermined conductivity and predetermined magnetically shielding properties.

In some examples, the top surface of the stage body can be configured to receive the sample-containing tape as it is relayed from the feeder reel to the take-up reel or from the take-up reel to the feeder reel. For example, in some embodiments, the sampling-containing tape can be received within a groove formed within the top surface of the stage body.

In some examples, the sample-containing tape is received with tension across the top surface of the stage body and wherein the sample-containing tape remains substantially flat.

In some examples, the feeder reel and the take-up reel are adapted to connect with an ultramicrotome (e.g., to facilitate sectioning and disposal of a plurality of samples on the tape). In certain examples, the sample-containing tape comprises a plurality of ultramicrotome samples.

In some examples, the assembly is detachably attached to a control unit. The control unit can be configured to control the predetermined speed of the feeder motor and the predetermined speed of the take-up motor. In some examples, the control unit can be configured to identify the positioning of each of a plurality of ultramicrotome samples on the sample-containing tape. In some examples, the control unit can be configured to rotate the feeder reel and the take-up reel to a predetermined position such that a predetermined sample of the plurality of ultramicrotome samples is imaged.

In some examples, the top surface of the stage body can further comprise at least two electrical connectors that are in intimate contact with at least a portion of the sampling-containing tape. The at least two electrical connectors can be configured to measure conductivity of a sample of the plurality of ultramicrotome samples. In certain examples, the at least two electrical connectors are in electrical communication with the control unit.

In some examples, the system can further comprise a device configured to transmit heat to the sample-containing tape.

Also disclosed herein is an electron microscope that comprises a system described herein operatively disposed within an electron microscopy stage.

Also disclosed herein are methods of sample imaging that comprise installing the system described herein within an electron microscope chamber and imaging a sample disposed above the imaging aperture. In some examples, the step of imaging can comprise collecting an SEM image, a BSE image, an EDX image, an EELS image, an Auger-SEM image, a light microscopy image, a fluorescence spectra, or a combination thereof. In certain examples, the step of imaging can comprise collecting an SEM image and a fluorescence spectra or image from the same sample.

Additional aspects of the disclosure will be set forth, in part, in the detailed description, figures, and claims which follow, and in part will be derived from the detailed description or can be learned by practice of the invention. It is to be understood that both the foregoing general description and the following detailed description are exemplary and explanatory only and are not restrictive of the invention as disclosed.

### BRIEF DESCRIPTION OF THE DRAWINGS

These and other features, aspects, and advantages of the present invention will become apparent from the following description and the accompanying exemplary implementations shown in the drawings, which are briefly described below.

FIG. 1 is a schematic illustration showing electron interaction volume within an epoxy resin embedded sample.

FIG. 2 shows an exploded view of an example imaging system according to one aspect.

FIG. 3 shows a perspective view, cross-sectional side view, top view, front view, and bottom view of an example stage according to one aspect.

FIG. 4 shows a perspective view, cross-sectional side view, top view, side view, and end view of an example coupler according to one aspect.

FIGS. 5A-5B illustrate an example coupler seated within the chamber of an example stage according to one aspect.

FIG. 6 shows an example coupler according to one aspect.

FIG. 7 shows an example coupler according to one aspect.

FIGS. 8A-8C show an example coupler according to one aspect.

FIGS. 9A-9C show an example coupler according to one aspect.

FIG. 10 illustrates an example t-block adaptor with a stage engaged in one aspect.

FIG. 11 illustrates an example reel-to-reel assembly operatively coupled to a stage in one aspect.

FIGS. 12A-12B illustrate an example reel-to-reel assembly according to one aspect.

FIG. 13 illustrates an example electron microscope stage according to one aspect.

FIGS. 14A-14C illustrate example systems described herein disposed within an electron microscope.

FIG. 15 illustrates an example system according to one aspect.

### DETAILED DESCRIPTION

The present invention can be understood more readily by reference to the following detailed description, examples, drawings, and claims, and their previous and following description. However, before the present assemblies, systems, and/or methods are disclosed and described, it is to be understood that this invention is not limited to the specific or exemplary aspects of assemblies, systems, and/or methods disclosed unless otherwise specified, as such can, of course, vary. It is also to be understood that the terminology used herein is for the purpose of describing particular aspects only and is not intended to be limiting.

The following description of the invention is provided as an enabling teaching of the invention in its best, currently known aspect. To this end, those skilled in the relevant art will recognize and appreciate that many changes can be made to the various aspects of the invention described herein, while still obtaining the beneficial results of the present invention. It will also be apparent that some of the desired benefits of the present invention can be obtained by selecting some of the features of the present invention without utilizing other features. Accordingly, those of ordinary skill in the pertinent art will recognize that many modifications and adaptations to the present invention are possible and can even be desirable in certain circumstances and are a part of the present invention. Thus, the following description is again provided as illustrative of the principles of the present invention and not in limitation thereof.

### Definitions

As used in this application and the claims, the singular forms “a,” “an,” and “the” include the plural forms unless the context clearly dictates otherwise. Thus, for example, a reference to a “reel” includes aspects having two or more such reels unless the context clearly indicates otherwise.

It is appreciated that certain features of the disclosure, which are, for clarity, described in the context of separate aspects, can also be provided in combination in a single aspect. Conversely, various features of the disclosure, which are, for brevity, described in the context of a single aspect, can also be provided separately or in any suitable combination.

As used herein, the terms “optional” or “optionally” mean that the subsequently described event or circumstance can or cannot occur and that the description includes instances where said event or circumstance occurs and instances where it does not.

It is also to be understood that the terminology used herein is for the purpose of describing particular aspects only and is not intended to be limiting. As used in the specification and the claims, the term “comprising” can include aspects of “consisting of” and “consisting essentially of.” Additionally, the term “includes” means “comprises.”

For the terms “for example” and “such as,” and grammatical equivalences thereof, the phrase “and without limitation” is understood to follow unless explicitly stated otherwise. Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in their respective testing measurements. Furthermore, when numerical ranges of varying scope are set forth herein, it is contemplated that any combination of these values inclusive of the recited values can be used. Further, ranges can be expressed herein as from “about” one particular value, and/or to “about” another particular value. When such a range is expressed, another aspect includes from the one particular value and/or to the other particular value.

Similarly, when values are expressed as approximations, by use of the antecedent “about,” it will be understood that the particular value forms another aspect. It will be further understood that the endpoints of each of the ranges are significant both in relation to the other endpoint and independently of the other endpoint. Unless stated otherwise, the term “about” means within 5% (e.g., within 2% or 1%) of the particular value modified by the term “about.”

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6, etc., as well as individual numbers within that range, for example, 1, 2, 2.7, 3, 4, 5, 5.3, 6 and any whole and partial increments therebetween. This applies regardless of the breadth of the range.

As used herein, the term “substantially” means that the subsequently described event or circumstance completely occurs or that the subsequently described event or circumstance generally, typically, or approximately occurs.

Further, the terms “coupled” and “associated” generally means electrically, electromagnetically, and/or physically (e.g., mechanically or chemically) coupled or linked and does not exclude the presence of intermediate elements between the coupled or associated items.

It will be understood that, although the terms “first,” “second,” etc. can be used herein to describe various elements, components, regions, layers and/or sections. These elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example aspects.

Spatially relative terms, such as “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

Numerous other general purpose or special purpose computing devices environments or configurations can be used. Examples of well-known computing devices, environments, and/or configurations that can be suitable for use include, but are not limited to, personal computers, server computers, handheld or laptop devices, multiprocessor systems, microprocessor-based systems, network personal computers (PCs), minicomputers, mainframe computers, embedded systems, distributed computing environments that include any of the above systems or devices, and the like.

Computer-executable instructions, such as program modules, being executed by a computer, can be used. Generally, program modules include routines, programs, objects, components, data structures, etc. that perform particular tasks or implement particular abstract data types. Distributed computing environments can be used where tasks are performed by remote processing devices that are linked through a communications network or other data transmission medium. In a distributed computing environment, program modules and other data can be located in both local and remote computer storage media, including memory storage devices.

In its most basic configuration, a computing device typically includes at least one processing unit and memory. Depending on the exact configuration and type of computing device, memory can be volatile (such as random-access memory (RAM)), non-volatile (such as read-only memory (ROM), flash memory, etc.), or some combination of the two.

Computing devices can have additional features/functionality. For example, a computing device can include additional storage (removable and/or non-removable) including, but not limited to, magnetic or optical disks or tape.

Computing devices typically include a variety of computer-readable media. Computer-readable media can be any available media that can be accessed by the device and includes both volatile and non-volatile media, removable and non-removable media.

Computer storage media include volatile and non-volatile, and removable and non-removable media implemented in any method or technology for storage of information such as computer-readable instructions, data structures, program modules or other data. Memory, removable storage, and non-removable storage are all examples of computer storage media. Computer storage media include, but are not limited to, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by a computing device. Any such computer storage media can be part of a computing device.

Computing devices, as disclosed herein, can contain communication connection(s) that allow the device to communicate with other devices. Computing devices can also have input device(s) such as a keyboard, mouse, pen, voice input device, touch input device, etc. Output device(s) such as a display, speakers, printer, etc. can also be included. All these devices are well known in the art and need not be discussed at length here.

It should be understood that the various techniques described herein can be implemented in connection with hardware components or software components or, where appropriate, with a combination of both. Illustrative types of hardware components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc. The methods and apparatus of the presently disclosed subject matter, or certain aspects or portions thereof, can take the form of program code (i.e., instructions) embodied in tangible media, such as CD-ROMs, hard drives, or any other machine-readable storage medium where, when the program code is loaded into and executed by a machine, such as a computer, the machine becomes an apparatus for practicing the presently disclosed subject matter.

Although the operations of exemplary aspects of the disclosed method can be described in a particular, sequential order for convenient presentation, it should be understood that disclosed aspects can encompass an order of operations other than the particular, sequential order disclosed. For example, operations described sequentially can, in some cases, be rearranged or performed concurrently. Further, descriptions and disclosures provided in association with one particular aspect are not limited to that aspect and can be applied to any aspect disclosed.

While aspects of the present invention can be described and claimed in a particular statutory class, such as the system statutory class, this is for convenience only, and one of ordinary skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred in any respect. This holds for any possible non-express basis for interpretation, including matters of logic with respect to arrangement of steps or operational flow, plain meaning derived from grammatical organization or punctuation, or the number or type of aspects described in the specification.

Moreover, for the sake of simplicity, the attached figures cannot show the various ways (readily discernable, based on this disclosure, by one of ordinary skill in the art) in which the disclosed system, method, and apparatus can be used in combination with other systems, methods, and apparatuses. Additionally, the description sometimes uses terms such as “produce” and “provide” to describe the disclosed method. These terms are high-level abstractions of the actual operations that can be performed. The actual operations that correspond to these terms can vary depending on the particular implementation and are, based on this disclosure, readily discernible by one of ordinary skill in the art.

The present invention can be understood more readily by reference to the following detailed description of various aspects of the invention and the examples included therein and to the Figures and their previous and following description.

### Systems and Methods

Provided herein are improved devices, systems, and methods for use in conjunction with electron microscopy.

For example, provided herein are improved systems and devices for use in electron microscopy. These can include in-column systems (including mirror adaptors and couplers) for use in conjunction with electron microscopy. These systems and devices can be used to conduct imaging (e.g., light microscopy or fluorescence microscopy) within the chamber of an electron microscope while allowing elements of the system (e.g., the detector and/or light source) to reside outside of the vacuum chamber. Aspects of these systems and devices can be deployed in conjunction with the systems and devices described in PCT Application No. PCT/US2020/045239, entitled “Electron Microscope Imaging Adaptor”, filed Aug. 6, 2020, which is incorporated herein by reference in its entirety. In some examples, the systems and devices described herein can be used to perform correlative light and electron microscopy (CLEM; a combination of fluorescence microscopy (FM) and high-resolution electron microscopy (EM)).

Aspects of this disclosure relate to economical, compact devices and systems developed under the acronym “STAR,” which stands for “Scanning Transmission, Arraytome, Reel-to-Reel Microscopy.” Generally, this is a microscopy system that accommodates sample preparation with a commercial microtome and numerous specialized attachment accessories and tools that adapt the microtome for more efficient sample delivery and a direct transfer of the prepared samples to an electron microscope system for imaging using a range of imaging techniques. The systems described herein can be used in conjunction with other elements of the STAR microscopy system, for example, to perform correlative light and electron microscopy on samples, including samples disposed on a sample containing tape.

Co-pending and commonly owned international PCT Application Serial No. PCT/US2019/013051, “Conductive Fixation of Organic Material,” filed Jan. 10, 2018, and U.S. Provisional Application Ser. No. 62/778,140 “Graphene Based Substrates for Imaging,” filed on Dec. 11, 2018, discuss the graphene substrates in more detail, and are incorporated herein by reference as if set forth in their entireties. Co-pending and commonly owned International PCT Application Serial No. PCT/US2020/045239, “Electron Microscope Imaging Adaptor,” filed Aug. 6, 2020, and International PCT Application Serial No. PCT/US2020/045233, “Apparatus and Methods for Ultramicrotome Specimen Preparation, filed Aug. 8, 2020, and international PCT Application Serial No. PCT/US2021/044741, “Coater for the Preparation of Carbon-Based Tape Substrates for Use in Imaging Applications,” filed Aug. 5, 2021, discuss component, systems, and methods for use in conjunction with the devices and systems described herein, and are incorporated herein by reference as if set forth in their entireties.

Referring now to FIG. 2, described herein are imaging systems (100) that comprise a stage (102) adapted to be deployed within an electron microscopy stage, a coupler (124) adapted to be disposed within the stage, and an optical element (132) connected to the coupler. When assembled, a path along which light can travel is generated, stretching from the optical element (132) to an imaging aperture (118) formed within a top surface (112) of the stage, thus permitting imaging (e.g., fluorescence microscopy) of a sample disposed above the imaging aperture when an appropriate light source and detector are interfaced with the optical element.

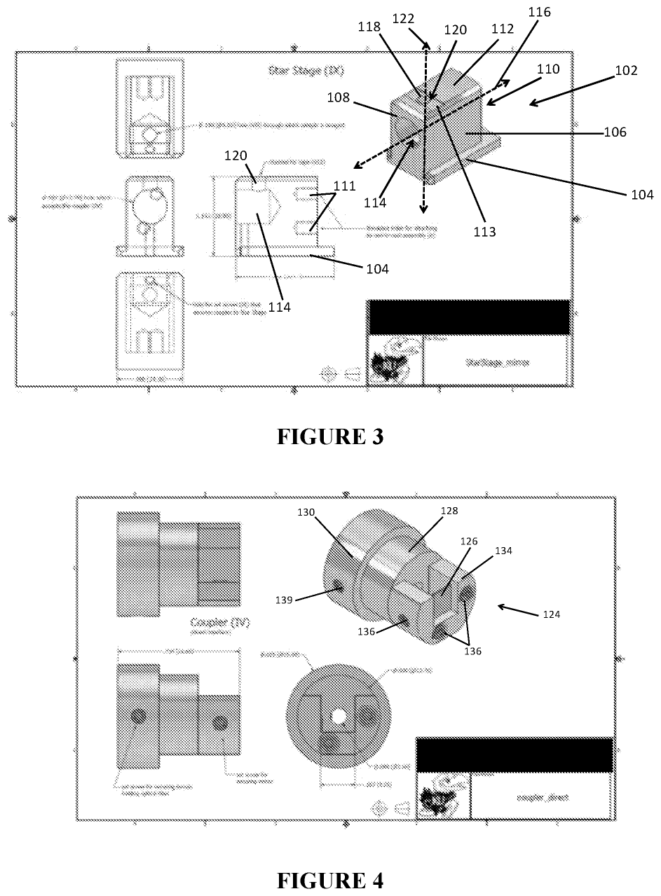

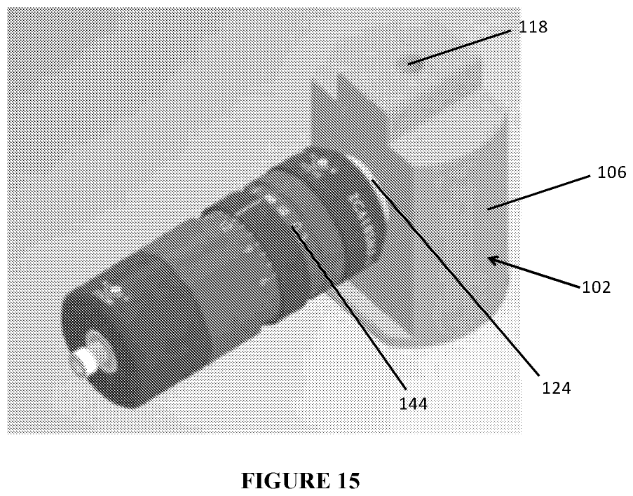

Referring now to FIG. 3, the stage (102) can comprise a base plate (104) dimensioned to be received and seated within an electron microscopy stage and a stage body (106) extending vertically from the base plate. The stage body (106) can comprise a front face (108), a rear face (110), and a top surface (112). As shown in FIG. 3, in certain embodiments, the stage body can have a generally cuboid shape. However, other shapes are in principle possible. For example, FIG. 15 shows a stage (102) in which the stage body (106) possesses curved sides.

Referring again to FIG. 3, the stage body (106) can further comprise a hollow chamber (114) formed within the stage body and extending from the front face (108) towards the opposing rear face (110) along an axis substantially parallel to the base plate (116). As shown in FIG. 3, in certain embodiments, the chamber can have a substantially cylindrical shape. The stage body (106) can further comprise an imaging aperture (118) formed within the top surface (112) and a beam path (120) extending from the imaging aperture (118) through the stage body (106) to the chamber (114) along an axis substantially perpendicular to the base plate (122).

Referring now to FIG. 4, the imaging system further comprises a coupler (124) sized to be advanced and seated within the hollow chamber (114). In some examples, the coupler can be substantially cylindrical and sized to be advanced and seated within a substantially cylindrical chamber. The coupler (124) can comprise a reflector (126) disposed within a housing (128) and a fastener (130) structured to operatively couple an optical element (132) to the housing (128).

The reflector (126) can comprise any suitable surface, interface, or object that can efficiently reflect and redirect incident light. For example, in some cases, the reflector can comprise a mirror, a mirror body, or a polished metal surface. In some examples, the reflector (126) can be retained within an adjustable bracket (134). One or more set screws (136) can be coupled to the adjustable bracket (134) such that rotation of the one or more set screws adjusts the orientation of the reflector (126). This can allow a user to adjust the optical alignment of the reflector (126) relative to the optical element (132), beam path (120), and imaging aperture.

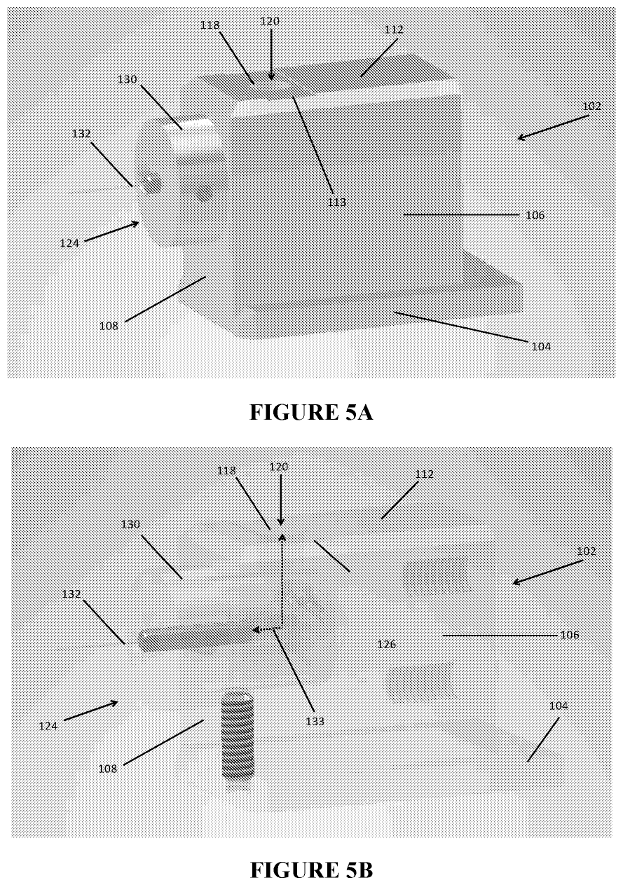

FIGS. 5A-5B illustrate a coupler (124) seated within the chamber (114) of an example stage (102). As shown in FIG. 5B, when the optical element (132) is operatively coupled to the housing via the fastener (130) and the coupler (124) is seated within the chamber (114), the optical element (132), reflector (126) and beam path (120) are aligned so as to crease a path (133) for light to travel from the optical element to the reflector through the beam path and the imaging aperture (118).

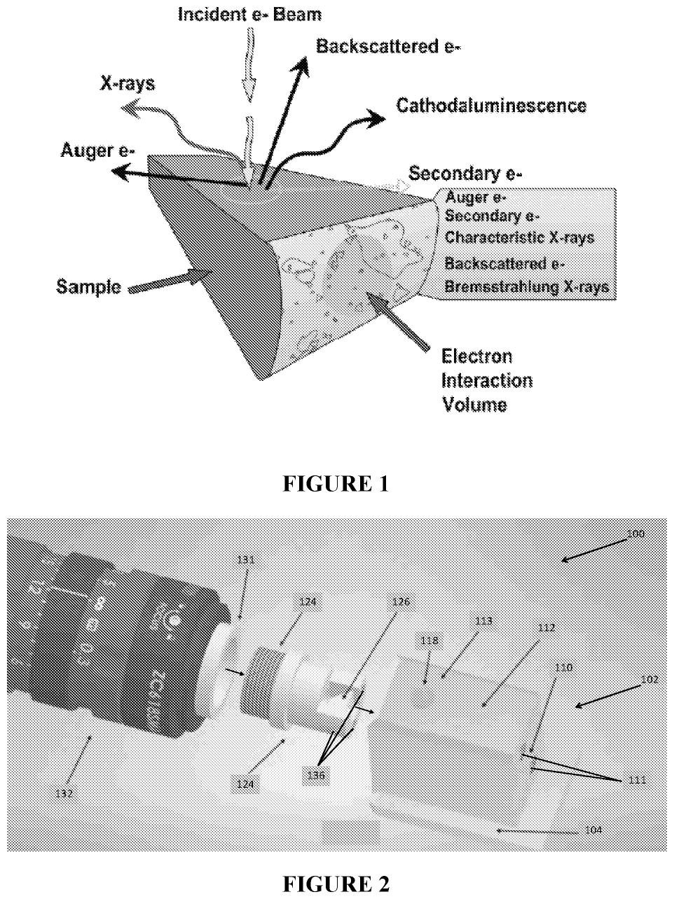

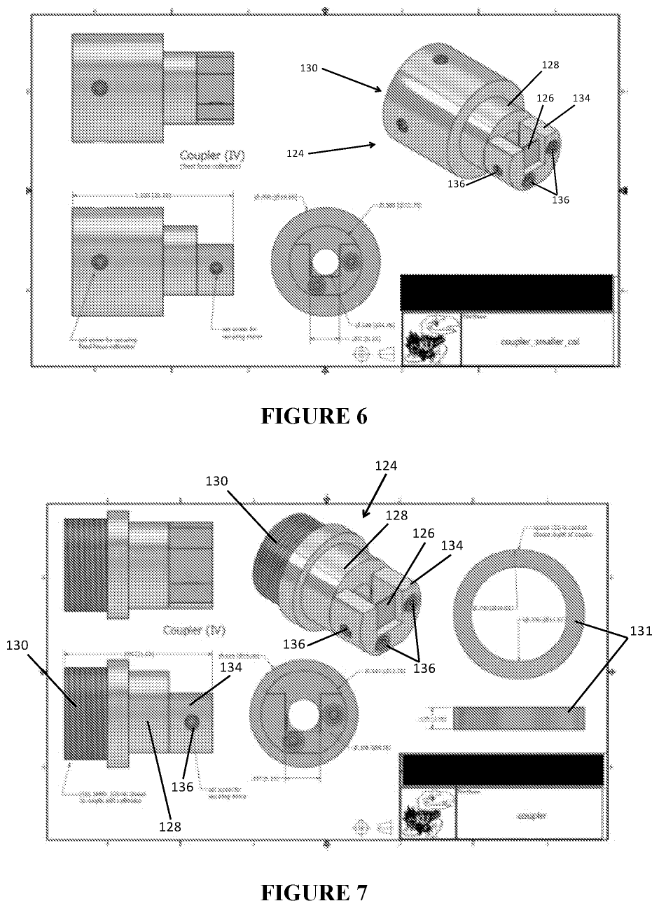

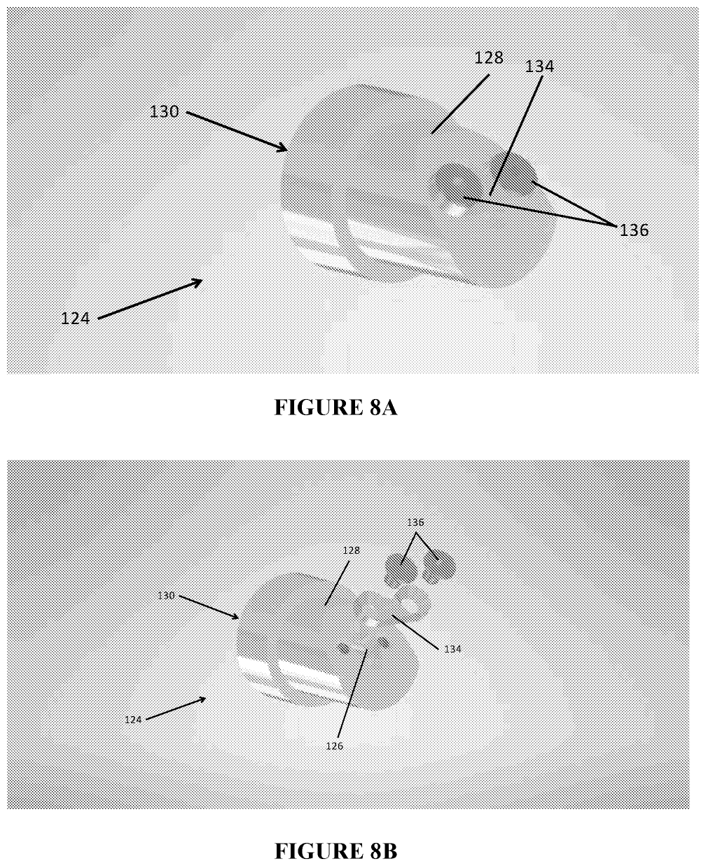

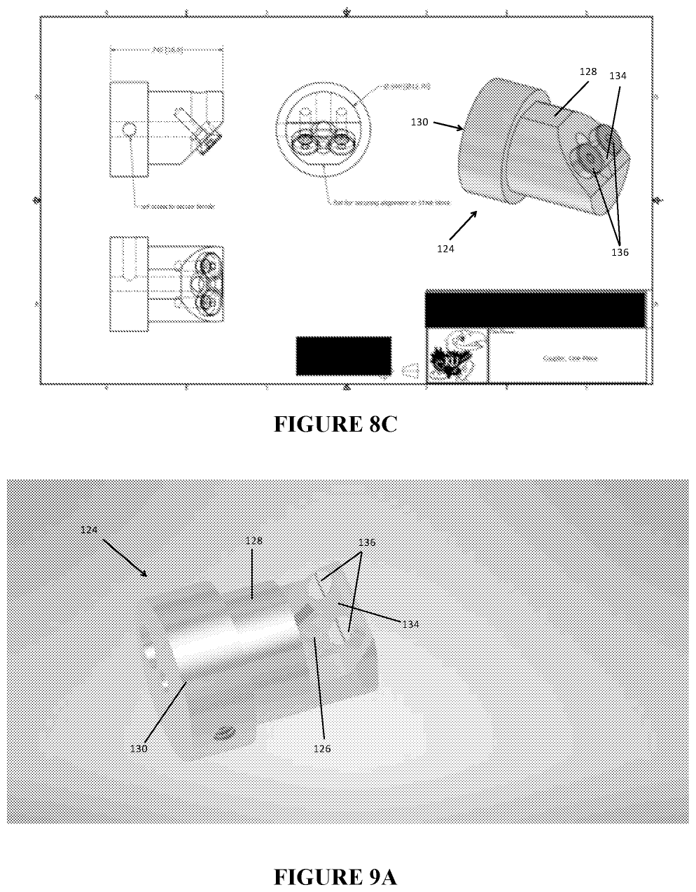

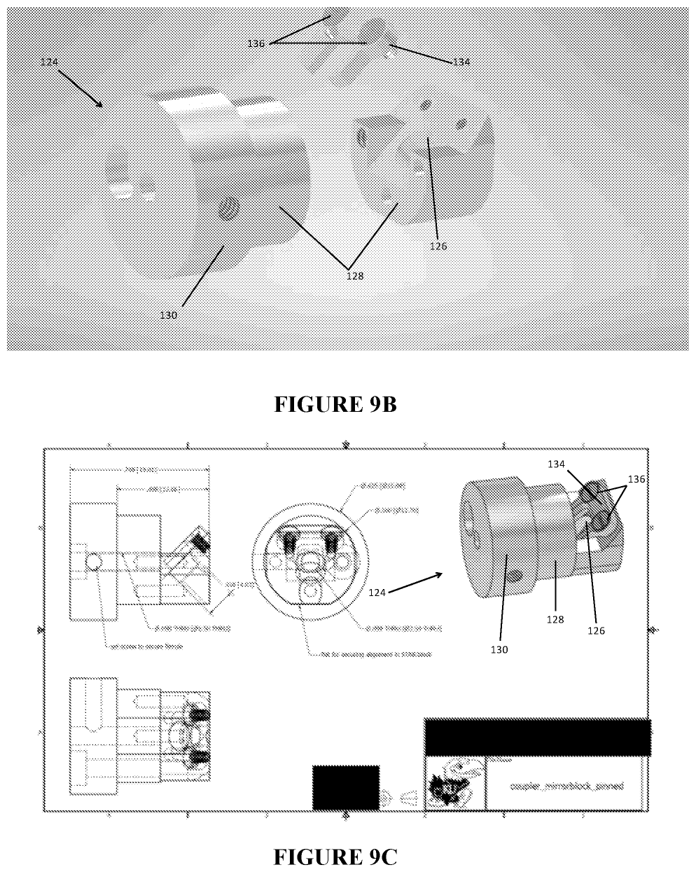

FIGS. 6, 7, 8A-8C, and 9A-9C illustrate other example couplers. As shown in FIG. 4, in some embodiments, the fastener (130) can comprise a ferrule sized to accept a fiber optic cable. Optionally, the fastener can further comprise a set screw (139) which can be tightened to secure the optical element (e.g., the fiber optic cable) within the fastener. As shown in FIG. 6, in other embodiments, the fastener can comprise a threaded fastener (130). The threaded fastener can be dimensioned to couple to the optical element (e.g., a collimator, as illustrated in FIG. 1, which can then be operatively connected to a fiber optic cable)

In some of these embodiments, the fiber optic cable can comprise a multistrand fiber optic cable (e.g., a 2-channel fiber optic cable). The first strand of the multistrand fiber optic cable can be optically connected to a light source (e.g., one or more LEDs, or a laser) and a second strand of the multistrand fiber optic cable is optically connected to a detector (e.g., a digital camera or a PMT).

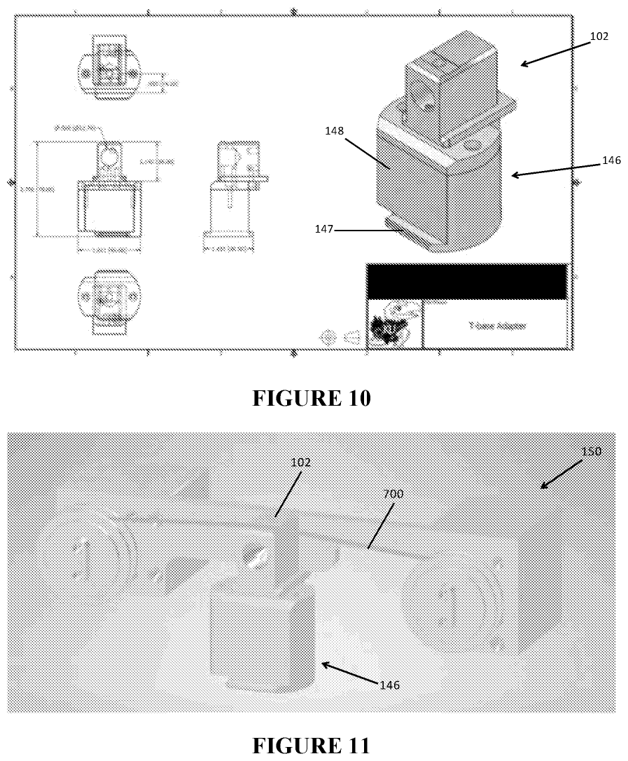

In some embodiments, the system can further comprise a t-block adaptor (146) comprising a body portion (148) and a base portion (149) as shown in FIG. 10. In these embodiments, the base plate (104) of the stage (102) can be reversibly engaged and coupled with the body portion (148) of the t-block adaptor (146). The base portion (149) of the t-block adaptor (146) can be dimensioned to be received and seated within an electron microscopy stage.

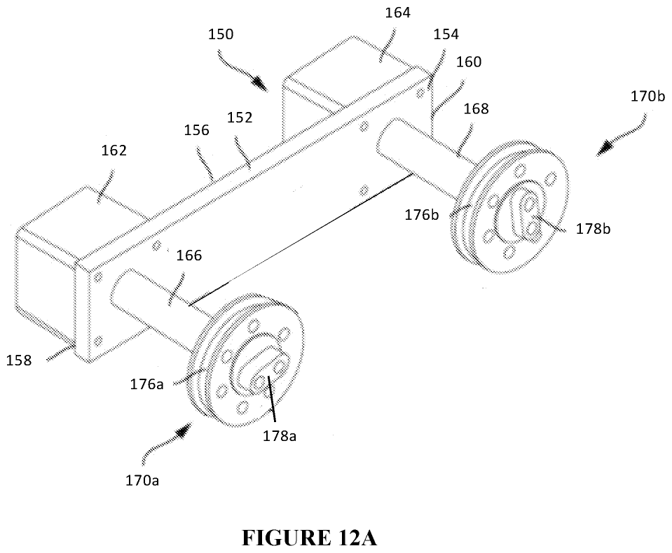

Referring now to FIG. 11, in some examples, the system can further comprise a reel-to-reel frame assembly (150) operatively coupled to the stage (102). In some examples, the reel-to-reel frame assembly can be operatively coupled to the stage via a mounting bracket fastened to the rear face (110) of the stage body (106). In certain embodiments, the rear face of the stage can comprise one or more threaded holes (111, see, for example FIG. 1) adapted to receive fasteners for attaching the reel-to-reel frame assembly to the stage.

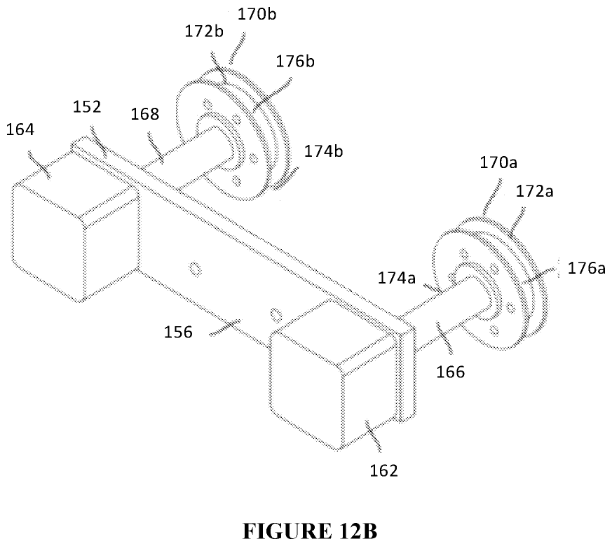

Referring now to FIGS. 12A-12B, the reel-to-reel frame assembly (also referred to as a “frame”) (150) can comprise a strut (152) having a first surface (154) and an opposite second surface (156), a first end (158) and a second end (160). As further can be seen, the strut (152) detachably holds: a feeder motor (162) and a take-up motor (164) coupled to the second surface (156) of the strut (152) such that the feeder motor is spaced from the take-up motor by a predetermined distance. It is understood that the specific positioning of the motor can be determined by one of ordinary skill in the art and will depend on a specific application (for example, a specific model of an electron microscope, chamber size, loading method, etc.).

In still further aspects, and as shown in FIGS. 12A-12B, the strut (152) further detachably holds a first rod (166) and a second rod (168). In certain aspects, the first rod (166) is detachably coupled with the feeder motor (162) through the strut (152), such that the first rod (166) extends from the first surface (154) of the strut (152). In still further aspects, the feeder motor (162) is configured to spin the first rod (166) at a predetermined speed. It is understood that the predetermined speed of the feeder motor (162) can be determined based on the desired application.

In still further aspects, the second rod (168) is detachably coupled with the take-up motor (164) through the strut (152), such that the second rod (168) extends from the first surface (154) of the strut (152). In still further aspects, the take-up motor (164) is configured to spin the second rod (168) at a predetermined speed. It is understood that the predetermined speed of the take-up motor (164) can be determined based on the desired application.

In still further aspects, it is understood that the predetermined speed for rotating the first rod can be the same or different as the predetermined speed of rotating the second rod. In certain and unlimiting aspects, the predetermined speed for rotating the first rod can be faster than the predetermined speed of rotating the second rod. Yet in still further aspects, the predetermined speed for rotating the first rod can be slower than the predetermined speed of rotating the second rod. While in still further aspects, the predetermined speed for rotating the first rod is substantially the same as the predetermined speed of rotating the second rod.

In yet further aspects, the strut (152) detachably holds a feeder reel (170a) having a top portion (172a) and a bottom portion (174a) that is detachably and rotatably coupled to the first rod (166). Further, the strut (152) also detachably holds a take-up reel (170b) having a top portion (172b) and a bottom portion (174b) and wherein the take-up reel is detachably and rotatably coupled to the second rod (168). In still further aspects, the feeder reel and the take-up reel, each comprises two wheels (178a) and (178b) connected with a spool (176a) and (176b) respectively, wherein each spool (sometimes referred to as a hub) is adapted for receiving and relaying the sample-containing tape (not shown).

In still further aspects, the wheels of the reel and the spool can be made of any material that can be adapted for use in an electron microscope and/or high vacuum. In certain and unlimited aspects, the wheels can comprise any materials that have predetermined conductivity and predetermined magnetically shielding properties. In yet further exemplary aspects, each of the two wheels and the spool can comprise aluminum and/or aluminum alloy having predetermined conductivity and predetermined magnetically shielding properties. It is understood that the materials used herein exhibit shielding against magnetic fields. In still further aspects, however, that aluminum and aluminum alloys are only exemplary materials and other materials can be used. For example, and without limitation, each of the two wheels and the spool can comprise one or more of carbon, copper, chromium, brass, iron, molybdenum, nickel, stainless steel, titanium alloys.

In still further aspects, each part of the disclosed herein assembly can be made by any known in the art methods. In one aspect, each of the parts of the disclosed herein assembly could be made by precise machining of the desired materials. However, in yet other aspects, each or any part of the disclosed herein assembly can be done by 3D printing.

In yet further aspects, it is understood that the strut, the first and the second rod, the mounting bracket, the reels are made of the same material. In still further aspects, the material can be any material that can be adapted for use in an electron microscope and/or high vacuum. In still further aspects, the material can comprise aluminum and/or aluminum alloy having predetermined conductivity and predetermined magnetically shielding properties. In still further aspects, the mounting bracket comprises aluminum and/or aluminum alloy having predetermined conductivity and predetermined magnetically shielding properties. In still further aspects, the first and the second rod comprise aluminum and/or aluminum alloy having predetermined conductivity and predetermined magnetically shielding properties. In yet further aspects, the strut comprises aluminum and/or aluminum alloy having predetermined conductivity and predetermined magnetically shielding properties. In yet further aspects, the motors can be covered with a mu-metal shell. It is understood that the mu-metal shell can comprise a nickel-iron soft ferromagnetic alloy having high permeability. In such aspects, the use of a mu-metal shell allows shielding of the motor's circuitry against magnetic fields and X-rays.

It is further understood that each part of the disclosed herein assembly is produced from materials and compositions are capable of withstanding temperatures inside of in-situ electron microscopes that are equipped to use a reel-to-reel imaging system. Such temperatures in the environment of an electron microscope can be in the range up to about 1,500° C., including exemplary values of about 900° C., about 1,000° C., about 1,100° C., about 1,200° C., about 1,300° C., and about 1,400° C. to the range of 1400 degrees Celsius to 1500 degrees Celsius.

In still further aspects, each of the wheels and the spool that are comprising disclosed herein reels have a calibrated circumference produced by precise machining of the desired materials, such as, for example, and without limitation, aluminum and aluminum alloy. In yet further aspects, these parts can be produced by precise machining of other materials, such as carbon, copper, chromium, brass, iron, molybdenum, nickel, stainless steel, titanium alloys. In still further aspects, the reels are adapted to maintain the first speed and the second speed such that the sample-containing tape can extend with tension, when desired, between the feeder reel and the take-up reel.

In yet further aspects, the feeder reel (170a) is configured to relay a sample-containing tape (not shown) to the take-up reel (170b) at a first speed, and wherein the reel-to-reel assembly is adapted for use in an electron microscope chamber. In still further aspects, the take-up reel is configured to send the sample-containing tape back to the feeder reel at a second speed. It is understood that the first speed for the feeder reel can be the same or different as the second speed of the take-up reel. In certain aspects and without limitation, the first and the second speeds can be up to about 4,000 rpm. In yet further aspects, the first and the second speed can be in any range between about 100 rpm and about 4,000 rpm, including exemplary values of about 250 rpm, about 500 rpm, about 750 rpm, about 1,000 rpm, about 1,250 rpm, about 1,500 rpm, about 1,750 rpm, about 2,000 rpm, about 2,250 rpm, about 2,500 rpm, about 2,750 rpm, about 3,000 rpm, about 3,250 rpm, about 3,500rpm, and about 3,750 rpm.

Still, in still further aspects, the first speed can be faster than the second speed. Yet in still further aspects, the first speed can be slower than the second speed. While in still further aspects, the first speed is substantially the same as the second speed. In still further aspects, the first speed can be substantially the same, slightly different, or different as compared to the predetermined speed for rotating the first rod. In still further aspects, the second speed can be substantially the same, slightly different, or different as compared to the predetermined speed for rotating the second rod. In yet further aspects, each speed described herein can be precisely controlled such that the same speed can be reproduced at any point in the imaging process if desired.

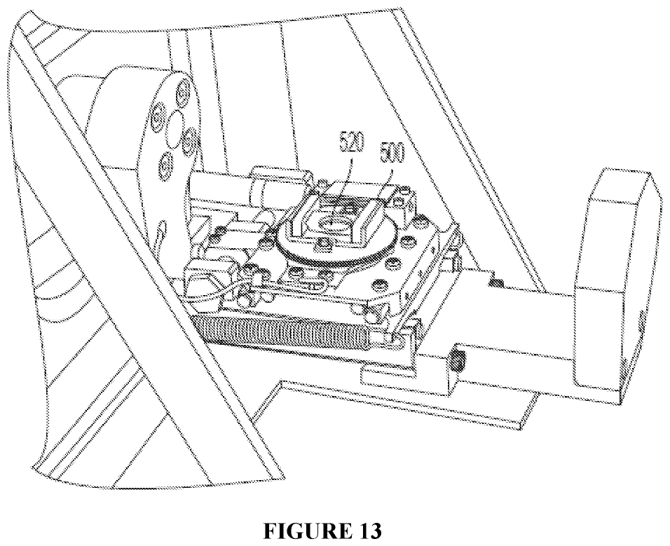

In certain exemplary aspects, the T-base adaptor (146), more specifically the base portion (149) of the T-base adaptor and/or the base plate (104) of the stage, as disclosed herein, can be used, for example, and without limitation, with any of the following scanning electron microscopes Hitachi's SU8000 series, SU8200 series, SU6600, SU-4700 and S-4800 FE-SEMs. In still further aspects, and as shown in the figures the T-base adaptor (146), more specifically the base portion (149) of the T-base adaptor and/or the base plate (104) of the stage, can comprise dovetails that allows stage and/or T-base to slidably mount the assembly on the electron microscope stage. The exemplary and unlimiting microscope stage 500 is shown in FIG. 13. Such an exemplary stage (500) is configured to slidably engage with the base plate (104) and to mount the assembly with the electron scope chamber. In still further aspects, the stage (500) can comprise an opening 520. It is understood that the height of the assembly can be monitored as it affects the positioning of the whole assembly within the chamber.

In still further aspects, a sample-containing tape (700) is relayed from the bottom portion (172a) of the feeder reel (170a) to the top surface (112) and to the bottom portion (174b) of the take-up reel (170b). In such aspects, the sample-containing tape is positioned on the top surface (112) of the stage (102) above the imaging aperture (118) with tension, again, to ensure that the sample-containing tape is substantially flat and stationary during the imaging. In yet some exemplary and unlimiting aspects, the sample-containing tape is positioned within a groove (113) and above the imaging aperture (118). It is understood that the term “stationary,” as used above, describes a specific state of the tape during the imaging steps, when motors are not spinning the rods and when reels do not move.

In yet further aspects, the sample-containing tape can also be relayed from the bottom portion (174b) of the take-up reel (170b) to the top surface (112) and to the bottom portion (174a) of the feeder reel (170a). In such aspects, the sample-containing tape moves backward from the take-up reel (170b) towards the feeder reel (170a).

It is understood that any tapes that have the desired conductivity can be used as sample-containing tapes. In certain aspects, the tapes used herein comprise graphene. In such exemplary and unlimiting aspects, graphene can uniformly coat one side of a 0.5-mil Polyimide Kapton Film (No Additional Adhesive) 6.4 mm [¼ inch] wide×33 m [36 yds] long (PIT0.5N/6.4). It is understood that the electrical conductivity of the tape can be controlled by controlling the graphene coating's thickness, ranging from tens of nanometers to hundreds of nanometers. Typically, for about 5-10 nm thickness of the graphene film, a sheet resistance of less than 45 ohm/square can be achieved.

In still further aspects, a special conductive fixation can also be used to provide the tape with the desired properties. Additional examples of various tapes that can be used as the sample-containing tapes are described in the co-pending and commonly owned patents, such as an International PCT Application Serial No. PCT/US2019/013051, “Conductive Fixation of Organic Material,” filed Jan. 10, 2018, and PCT Application Serial No. PCT US2019/065633, “Graphene Based Substrates for Imaging,” filed Dec. 11, 2019, the contents of which are incorporated herein in their whole entireties.

It is further understood that the sample-containing tapes are prepared by slicing the samples with an ultramicrotome on the tape to form a plurality of ultramicrotome samples. In certain aspects, the plurality of ultramicrotome samples comprise resin-based microscopic sections of cells and tissues that were sliced and positioned on the tape. The sample-containing tape can comprise thousands of ultra-thin (thickness of 50 nm or less) and/or semi-thin (thickness above 50 nm) sample sections that are automatically and continuously collected from a diamond knife edge onto a graphene-based, or other specialized material, surface. In some non-limiting aspects, the sample collection surfaces can include coated 0.5-mil Polyimide [Kapton] Film No Adhesive 6.4 mm [¼″] wide×33 m [36 yd] long (PIT0.5N/6.4). In yet further aspects, the samples obtained by ultramicrotome and disposed on the tape can be further manipulated as desired before imaging with an electron microscope. In still further aspects, the sample-containing tape can comprise any other samples, for example, such that can be prepared by focused ion beam milling (FIB), etc.

As discussed in detail above, the sample-containing tape then is sufficiently pliable to wind around spools (176a) and (172b) of the feeder reel (170a) and the take-up reel (170b) at a desirable tension between the reels.

In still further aspects, the feeder reel and the take-up reel that can be detachably attached to the frame disclosed above are also adapted to connect with an ultramicrotome. In such aspects, the reels are first used with an ultramicrotome device, and then the prepared samples winded around the spools are transferred to the disclosed herein assembly for use with the microscope.

In still further aspects, the reel-to-reel assembly is detachably attached to a control unit. In some aspects, the control unit is configured to control the predetermined speed of the feeder motor and the predetermined speed of the take-up motor. While in yet other aspects, the control unit is configured to identify the positioning of each of the plurality of ultramicrotome samples on the sample-containing tape. In yet further aspects, the control unit is configured to rotate the feeder reel and the take-up reel to a predetermined position such that a predetermined sample of the plurality of ultramicrotome samples is imaged.

It is further understood that the control unit used herein can also be used to obtain the plurality of ultramicrotome samples on the sample-containing tape. In such aspects, the same control unit is used for ultramicrotome and imaging.

In certain aspects, the control unit is in electrical communication with the motors of the assembly and with the stage of the assembly. In certain aspects, the control unit can be equipped to control the respective speed of the feeder motor and the take-up motor and to adjust those speeds according to a sample positioning.

The control unit can further comprise a graphical user interface. Such an interface can be configured to receive data entry for programming the control unit. The data entry can comprise programming of the optional parameters to maintain variables such as speed selections for the feeder motor and the take-up motor. It is understood that any motors that can achieve the desired function can be used. In some aspects, the motors can be stepper motors.

The control unit can be characterized as having general-purpose inputs and outputs that are connected to appropriate processors, computerized memory, and hardware that is appropriate for customized machine logical operations. In one non-limiting example, the control unit can receive data from a system of sensors, for example, during the ultramicrotome procedures, the control unit can receive data from a first cantilever arm position sensor and a second cantilever arm position sensor, either of which can be located on the cantilever arm and/or the body of the ultramicrotome. This data, along with speed data for the motors, can be used for numerous control systems programmed into the control unit. For example, in one aspect, by using the speed of the motors and the rotation speed of the reels, along with dimensions of the tape and linear speed of the tape, the control unit is adapted to track position coordinates of each cut resin section that is located on the tape. In this way, the control unit can comprise a computer registry or database that allows for tracking where a specimen is located along the tape and which sections of the tape are empty. In such aspects, the control unit allows imaging of a predetermined sample of the plurality of ultramicrotome samples. In yet further aspects, the control unit can allow sequential imaging of the sample, or it can allow the user to skip any sample by moving the tape to arrive at the desired sample location.

The control unit, as described herein, allows movement of the sample-containing tape from the feeder reel to a take-up reel. In certain aspects, the control unit can include a computer processor connected to computerized memory storing computer-implemented software implementing programmable, computerized steps of a method.

In certain aspects, the control unit needs to be manually calibrated to determine a specific position of the sample to be imaged. In such aspects, the calibrated unit can then automatically determine the position of the sample to be imaged on the sample-containing tape. In yet other aspects, the control unit does not require manual calibration. As the control unit can behave as a registry of the samples on the sample-containing tape, a user can direct the reels to the desired position. Such communication with the control unit can be done through the computer interface, for example. In still further aspects, the interface (or software) that communicates with the control unit can be further integrated with a software that directs the operation of the electron scanning microscope. In such aspects, the control unit software can be used independently or in combination with the electron microscope software.

In still further aspects, the control unit can comprise a specified firmware. In certain aspects, the control unit can comprise a firmware adapted for use with the ultramicrotome. In yet other aspects, the control unit can comprise a firmware adapted for use with an electron microscope. In yet further aspects, the control unit can comprise a firmware adapted for tape coating tools. It is understood that in some aspects, the control unit can comprise any or all of the disclosed above firmware. In still further aspects, each of the disclosed above firmware can comprise various modules configured to communicate between the control unit and a specific tool to perform the desired function.

In certain aspects, the control unit can comprise a tape control module that is configured to maintain a constant speed of the tape. In such aspects, the contact speed of tape can be controlled based on a precise diameter of the reels and their revolutions. In yet further aspects, the data related to the diameter and revolutions of the wheels can be used to control the speed of each of the feeder motor and the take-up motor In still further aspects, the tape control module can be configured to access the hardware settings of the motor controller on the board. In yet further aspects, the tape control module is configured to communicate using a transmission protocol with user software via the USB interface of the hardware.

In aspects disclosed herein, the control unit comprises an electron microscope controlling firmware. In such aspects, the firmware comprises the tape control module as disclosed. In yet further exemplary aspects, the control unit is configured to be connected with an analog joystick. In such exemplary aspects, the joystick can be configured to control the tape speed, tape direction as well as sample position during the manual mode. In certain aspects, such operation can be useful in centering the sample for imaging.

In still further aspects, the control unit is adapted to be operable with either an ultramicrotome, tape coating apparatus or an electron microscope. In certain aspects, the feeder motor can be detachably connected to an encoder. While in yet other aspects, the feeder motor is not connected to an encoder. In the aspects where no encoder is attached, a user can set an initial value for revolutions of the feeder reel and the take-up reel manually using an interface that is in communication with the control unit. In yet other aspects, where the encoder is connected to the feeder motor, only a value for revolutions of the take-up reel needs to be set. In such aspects, the control unit is configured to calculate the value for the revolution of the feeder reel automatically.

In yet further aspects, when the analog joystick is connected to the control unit, a user can use the joystick to center a first sample of the plurality of ultramicrotome samples manually with the joystick. In yet further exemplary aspects, the user can use the information collected during ultramicrotome processes to set a distance between the samples. In still further aspects, a scan time of the samples can also be set during the operation. In such aspects, the control unit is configured to pause the movement of the tape for a predetermined time to allow imaging to conclude. In still further aspects, the control unit is configured to continue the tape movement to a next sample when the scan time expires. The control unit is configured to continue this process any number of times as desired to continuously image the sample-containing tape. In yet further aspects, the control unit is configured to move the sample-containing tape back towards the feeder reel, for example, if a repeated image of a specific sample is needed.

In still further aspects, top surface of the stage body can comprise at least two electrical connectors that are in intimate contact with at least a portion of the sampling-containing tape. In some aspects, these electrical connectors can be positioned within the groove. In yet other aspects, if there is no groove present on the top surface of the stage, the electrical connector can be positioned on the top surface of the stage in intimate contact with the at least a portion of the sampling-containing tape. When the sample-containing tape is relayed from the feeder reel to the take-up reel and contact the at least two electrical connectors, the electrical connectors are configured to measure the conductivity of that portion of the sample-containing tape. The electrical connectors are in electrical communication with the control unit. In certain aspects, a four-point measurement can be used. In such aspects, the platform can comprise four electrical connectors.

It is understood that the systems can be used with many commercial electron microscopes, such for example, from FE-SEM of JEOL's, ZEISS's, Thermo Scientific's (previously FEI), and/or TESCAN. Since these scanning electron microscopes having various configurations, the disclosed herein assembly can adapted to be installed within any of these microscope's chambers.

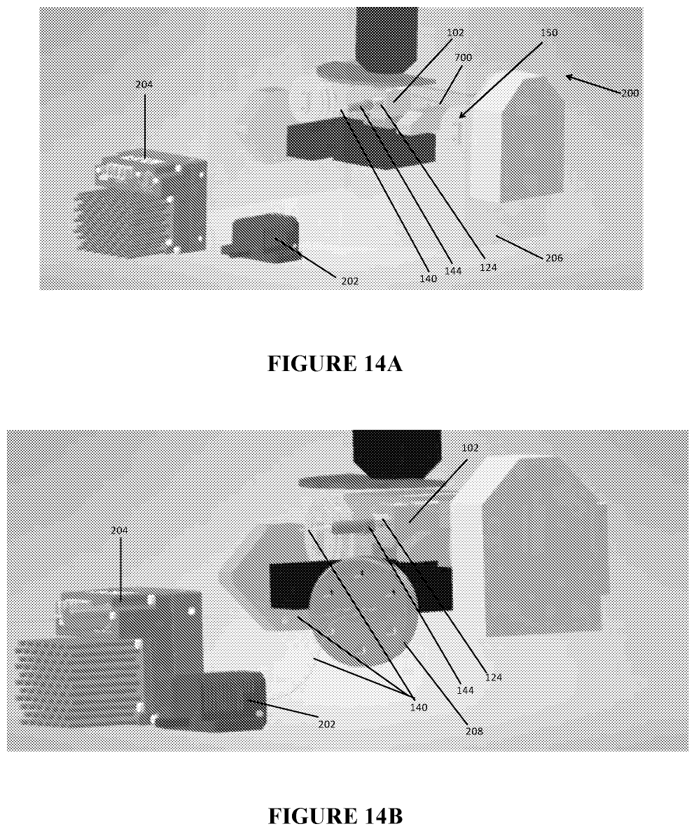

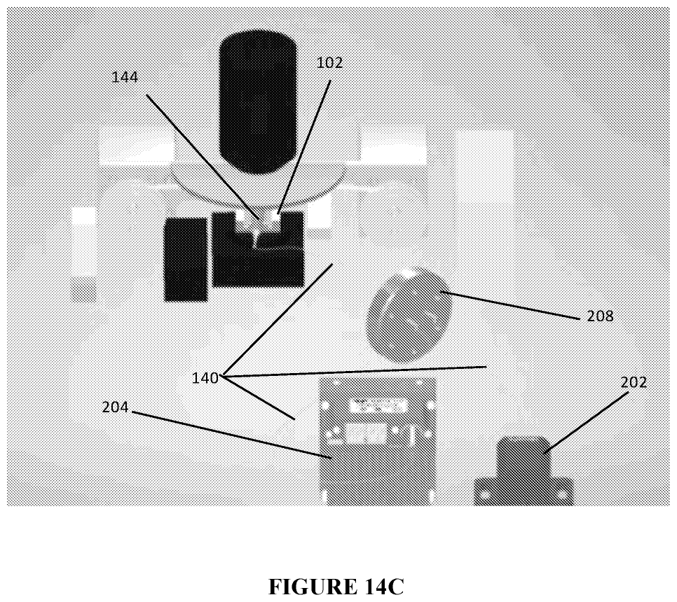

FIGS. 14A-14C illustrate example systems described herein disposed within an electron microscope (200). As shown in FIGS. 14A-14C, the stage (102), coupler (124), optical element (here, a collimator 144), and reel-to-reel assembly (150) are all disposed within the vacuum chamber (206). A fiber optic cable (140) optically connects collimator (144) to a light source (202, e.g., one or more LEDs, or a laser) and a detector (204, a digital camera or PMT). The light source and detector can be positioned outside of the vacuum chamber. A flange (208) can be installed in the wall of the vacuum chamber to allow passage of the fiber optic cable(s) (140) into the vacuum chamber while maintaining an airtight seal.

In some aspects, the system described herein can be adapted to imaging with a light microscope. Light microscopy techniques can comprise fluorescence microscopy. In some aspects, the imaging can comprise confocal fluorescence microscopy and/or epifluorescence microscopy. In certain aspects, fluorescence imaging can be done in 2D. In such aspects, the depth in the sample, which provides the 2D image can be controlled by the localized focusing of the light stimulation. While in other aspects, the fluorescence imaging can also be done in 3D by using a confocal approach. In yet further aspects, the electron microscope can be adapted for use with an inverted light microscope.

In still further aspects, any known in the art digital cameras can be used as a detector, for example, to capture the image. In some aspects, the detector can comprise sensors comprising CCD (Charge Coupled Devices) and/or sCMOS (scientific Complementary Metal Oxide Semiconductors). It is understood that the user can select an appropriate detector, such as a camera based on the desired sensitivity and signal-to-noise ratio. In certain aspects, it is understood that color cameras can have a different resolution and sensitivity than monochrome cameras. In certain aspects, the cameras used herein can be color cameras. While in other aspects, the cameras used herein can be monochrome.

In still further exemplary aspects and unlimiting aspects, the cameras used herein can comprise a monochrome sCMOS sensor comprising, 5 megapixels. The disclosed cameras can have a C-mount. In yet further exemplary aspects, the cameras can operate at a video rate of 10 frames per second (or up to 30 fps with reduced frame size). The image size is from 100×100 to 1900×1900 pixels. The camera is configured to provide images with JPG, BMP, TIG, and/or PNG format. In exemplary aspects disclosed herein, the detector is configured to collect light in 400-430 nm range (violet light) (660), in 465-500 nm range (green light) (640), and 580-620 nm range (orange light) (620).

In some aspects, images can be taken using either backscatter electron detector and/or secondary electrons detector using a field emission scanning electron microscope combined with a cathodoluminescence (CL) detector in the range of 7 keV (beam current) and 0.1 nA (probe current). The use of a retractable CL detector can be used to detect panchromatic CL signals from cell and/or tissue sections with a high signal-to-noise in the spectral range between 330-600 nm. The total CL intensity can be calculated and statistically analyzed using an internal ROI region (n=4) compared to areas outside of the ROI (n=4) that will represent background. This can be colocalized with an EM image, if desired.

The claims are not intended to include, and should not be interpreted to include, means-plus- or step-plus-function limitations, unless such a limitation is explicitly recited in a given claim using the phrase(s) “means for” or “step for,” respectively.

In view of the described processes and compositions, hereinbelow are described certain more particularly described aspects of the inventions. These particularly recited aspects should not, however, be interpreted to have any limiting effect on any different claims containing different or more general teachings described herein, or that the “particular” aspects are somehow limited in some way other than the inherent meanings of the language and formulas literally used therein.

1. An imaging system comprising:
a stage comprising
a base plate dimensioned to be received and seated within an electron microscopy stage; and
a stage body extending vertically from the base plate, the stage body comprising
a front face,
a rear face,
a top surface,
a hollow chamber formed within the stage body and extending from the front face towards the rear face along an axis substantially parallel to the base plate;
an imaging aperture formed within the top surface; and
a beam path extending from the imaging aperture through the stage body to the chamber along an axis substantially perpendicular to the base plate;
a coupler sized to be advanced and seated within the chamber, the coupler comprising a reflector disposed within a housing; and
a fastener structured to operatively couple an optical element to the housing, wherein when the optical element is operatively coupled to the housing via the fastener and the coupler is seated within the chamber, the optical element, reflector, and beam path are aligned so as to crease a path for light to travel from the optical element to the reflector through the beam path and the imaging aperture.

2. The system of claim 1, wherein the reflector comprises a mirror or polished metal surface.

3. The system of any of claims 1-2, wherein the reflector is retained within an adjustable bracket.

4. The system of claim 3, further comprising one or more set screws coupled to the adjustable bracket, wherein rotation of the one or more set screws adjusts the orientation of the reflector.

5. The system of any of claims 1-4, wherein the fastener comprises a ferrule sized to accept a fiber optic cable.

6. The system of any of claims 1-4, wherein the fastener comprises a threaded fastener dimensioned to couple to a collimator; wherein the collimator is operatively connected to a fiber optic cable.

7. The system of any of claims 5-6, wherein the fiber optic cable comprises a multistrand fiber optic cable, wherein a first strand of the multistrand fiber optic cable is optically connected to a light source and a second strand of the multistrand fiber optic cable is optically connected to a detector.

8. The system of any of claims 1-7, wherein the chamber is substantially cylindrical.

9. The system of any of claims 1-8, further comprising a reel-to-reel frame assembly operatively coupled to the stage.

10. The system of any of claims 1-9, wherein the reel-to-reel frame assembly is operatively coupled to the stage via a mounting bracket fastened to the rear face of the stage body.

11. The system of any of claims 9-10, wherein the reel-to-reel frame assembly comprises:
(a) a strut having a first surface and an opposite second surface, a first end and a second end, wherein the strut detachably holds:
i) a feeder motor and a take-up motor coupled to the second surface of the strut such that the feeder motor is spaced from the take-up motor by a predetermined distance;
ii) a first rod detachably coupled with the feeder motor through the strut, such that the first rod extends from the first surface of the strut, wherein the feeder motor is configured to spin the first rod at a predetermined speed, and
iii) a second rod detachably coupled with the take-up motor through the strut, such that the second rod extends from the first surface of the strut, wherein the take-up motor is configured to spin the second rod at a predetermined speed that is the same or different as the predetermined speed of rotations of the first rod; and
b) a feeder reel having a top portion and a bottom portion detachably and rotatably coupled to the first rod and a take-up reel having a top portion and a bottom portion detachably and rotatably coupled to the second rod;
wherein the feeder reel is configured to relay a sample-containing tape to the take-up reel at a first speed.

12. The system of claim 11, wherein the top surface of the stage body is configured to receive the sample-containing tape as it is relayed from the feeder reel to the take-up reel or from the take-up reel to the feeder reel.

13. The system of claim 12, wherein the sample-containing tape is received with tension across the top surface of the stage body and wherein the sample-containing tape remains substantially flat.

14. The system of any of claims 12-13, wherein the sampling-containing tape is received within a groove formed within the top surface of the stage body.

15. The system of any of claims 11-14, wherein the feeder reel and the take-up reel are adapted to connect with an ultramicrotome.

16. The system of any of claims 11-15, wherein the sample-containing tape comprises a plurality of ultramicrotome samples.

17. The system of any of claims 11-16, wherein the assembly is detachably attached to a control unit, wherein the control unit is configured to control the predetermined speed of the feeder motor and the predetermined speed of the take-up motor.

18. The system of claim 17, wherein the control unit is configured to identify the positioning of each of a plurality of ultramicrotome samples on the sample-containing tape.

19. The system of claim 17, wherein the control unit is configured to rotate the feeder reel and the take-up reel to a predetermined position such that a predetermined sample of the plurality of ultramicrotome samples is imaged.

20. The system of any one of claims 11-19, wherein the top surface of the stage body further comprises at least two electrical connectors that are in intimate contact with at least a portion of the sampling-containing tape.

21. The system of claim 20, wherein the at least two electrical connectors are configured to measure conductivity of a sample of the plurality of ultramicrotome samples.

22. The system of claim 20 or 21, wherein the at least two electrical connectors are in electrical communication with the control unit.

23. The system of any one of claims 11-22, further comprising a device configured to transmit heat to the sample-containing tape.

24. The system of any one of claims 11-23, wherein the feeder reel and the take-up reel, each comprises two wheels connected with a spool, wherein the spool is adapted for receiving and relaying the sample-containing tape.

25. The system of claim 24, wherein each of the two wheels and the spool comprises aluminum and/or aluminum alloy having predetermined conductivity and predetermined magnetically shielding properties.

26. The system of any one of claims 1-25, wherein the stage and the coupler are adapted for a high vacuum environment.

27. The system of any one of claims 1-26, further comprising a t-base adaptor coupled to the base plate of the stage.

28. An electron microscope comprising the system defined by any of claims 1-27.

29. A method of sample imaging comprising:
installing the system defined by any of claims 1-27 within an electron microscope chamber; and
imaging a sample disposed above the imaging aperture.

30. The method of claim 29, wherein the step of imaging comprising collecting an SEM image, a BSE image, an EDX image, an EELS image, an Auger-SEM image, a light microscopy image, a fluorescence spectra, or a combination thereof.
